(19) United States
(12) Patent Application Publication
(10) Pub. No.: US 2026/0290763 A1
(43) Pub. Date: Sep. 24, 2026

(54) METHOD FOR REMOVING BY-PRODUCT IN PLASMA ETCHING APPARATUS

(71) Applicants: TSMC China Company Limited, Shanghai (CN); TAIWAN SEMICONDUCTOR MANUFACTURING COMPANY, LTD., Hsinchu (TW)

(72) Inventors: Ming LI, Shanghai City (CN); Linzhou HUANG, Shanghai City (CN); Ran ZHAO, Shanghai City (CN); Lin MA, Shanghai City (CN)

(73) Assignees: TSMC China Company Limited, Shanghai (CN); TAIWAN SEMICONDUCTOR MANUFACTURING COMPANY, LTD., Hsinchu (TW)

(21) Appl. No.: 19/097,219

(22) Filed: Apr. 1, 2025

(30) Foreign Application Priority Data
Mar. 19, 2025 (CN) 202520493862.6

(51) Int. Cl. H01J 37/32

(52) U.S. Cl. CPC H01J 37/32834; H01J 37/3244; H01J 2237/3341

(57) ABSTRACT

A method includes following steps. A pressure within a chamber is reduced from a first pressure level to a second pressure level using a first pump. After reducing the pressure within the chamber to the second pressure level, a plasma etching operation is performed in the chamber. After performing the plasma etching operation, a pneumatic purging apparatus is placed onto the first pump. After placing the pneumatic purging apparatus onto the first pump, an interior space of the first pump is purged by ejecting a purging gas from the pneumatic purging apparatus.

### PRIORITY CLAIM AND CROSS-REFERENCE

The present application claims priority to China Application Serial Number 202520493862.6, filed Mar. 19, 2025, which is herein incorporated by reference.

### BACKGROUND

The dry etching process, including plasma etching, is a technique in the field of semiconductor manufacturing and microfabrication. Unlike wet etching, which uses liquid chemicals to remove material from a substrate, dry etching employs gases in a plasma state to achieve material removal. This process is helpful for creating intricate patterns and features on semiconductor wafers, which are foundational to the production of integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating an exemplary process for plasma etching apparatus operation and maintenance, in accordance with some embodiments of the present disclosure.

FIGS. 2-4A are schematic side views of a plasma etching apparatus, illustrating various stages of the plasma etching operation, in accordance with some embodiments of the present disclosure.

FIGS. 4B and 4C are cross-sectional views zoomed-in to the substrate W, respectively illustrating an initial stage and a final stage of the plasma etching operation, in accordance with some embodiments of the present disclosure.

FIG. 5 is a schematic side view of the plasma etching apparatus, illustrating the wafer-less auto clean (WAC) operation, in accordance with some embodiments of the present disclosure.

FIG. 6A is a schematic side view of the plasma etching apparatus, illustrating an initial stage of the pump purging operation, in accordance with some embodiments of the present disclosure.

FIG. 6B is a three-dimensional view of the pneumatic purging apparatus, in accordance with some embodiments of the present disclosure.

FIG. 6C is a top view of the turbo molecular pump, in accordance with some embodiments of the present disclosure.

FIG. 7 is a schematic side view of the plasma etching apparatus, illustrating a subsequent stage of the pump purging operation, in accordance with some embodiments of the present disclosure.

FIG. 8A illustrates a bottom view of the pneumatic purging apparatus, in accordance with some embodiments of the present disclosure.

FIG. 8B illustrates a zoomed-in cross-sectional view at a region where the pneumatic purging apparatus is placed onto the turbo molecular pump, in accordance with some embodiments of the present disclosure.

FIG. 9A illustrates a bottom view of another pneumatic purging apparatus, in accordance with some embodiments of the present disclosure.

FIG. 9B illustrates a zoomed-in cross-sectional view at a region where the pneumatic purging apparatus is placed onto the turbo molecular pump, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

Semiconductor processing equipment, such as plasma etching systems, plasma-enhanced chemical vapor deposition (PE-CVD) systems, and sputtering systems, are used extensively throughout the production of integrated circuits (ICs). This semiconductor processing equipment may contain a processing chamber that helps contain the often reactive processes performed by this equipment. Due to these processes, by-products may form on in the semiconductor processing equipment resulting in decreased performance and/or contamination of the equipment, which may result in a decrease in the yield of ICs.

To maintain equipment efficiency and improve IC yield, regular cleaning processes are performed to remove by-product buildup. For instance, during plasma etching, a workpiece is placed into the processing chamber. This workpiece usually includes a patterned photoresist layer over an etching target layer, such as a dielectric layer (e.g., silicon oxide, silicon nitride) or a metal layer (e.g., copper, titanium nitride). The plasma etching apparatus generates plasma within the processing chamber to selectively etch the target layer. During etching, non-volatile by-products are produced, which can accumulate on various components of the apparatus, such as the chamber sidewalls and the blades of a vacuum pump such as a turbo molecular pump (TMP), which serves to pump the chamber down to vacuum and maintain the vacuum environment.

As the workpiece or subsequent workpieces are processed, these by-product particles may detach from the chamber sidewalls or pump blades and contaminate the workpiece, potentially leading to defective ICs. To mitigate this, wafer-less auto clean (WAC) processes are employed to remove by-product particles from the chamber sidewalls. However, WAC is less effective at cleaning the pump blades due to limited plasma reach.

To address this limitation, the present disclosure in various embodiments provides a method and an apparatus for effectively removing by-product particles from pump blades. This method includes purging the interior of the vacuum pump using a pneumatic purging apparatus, complementing the WAC process that cleans the chamber sidewalls using plasma. By blowing a gas flow into the vacuum pump's interior, by-product particles can be efficiently removed from the pump blades, enhancing overall cleanliness of etching apparatus.

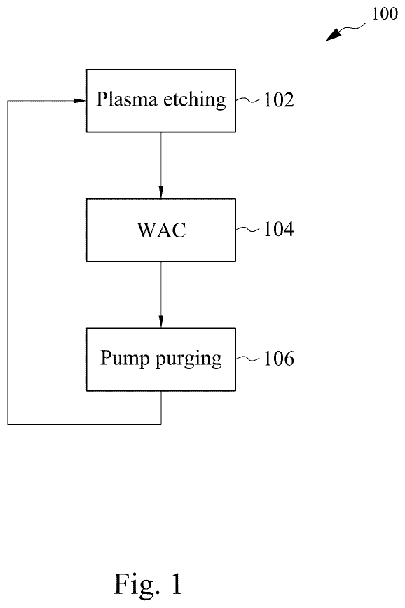

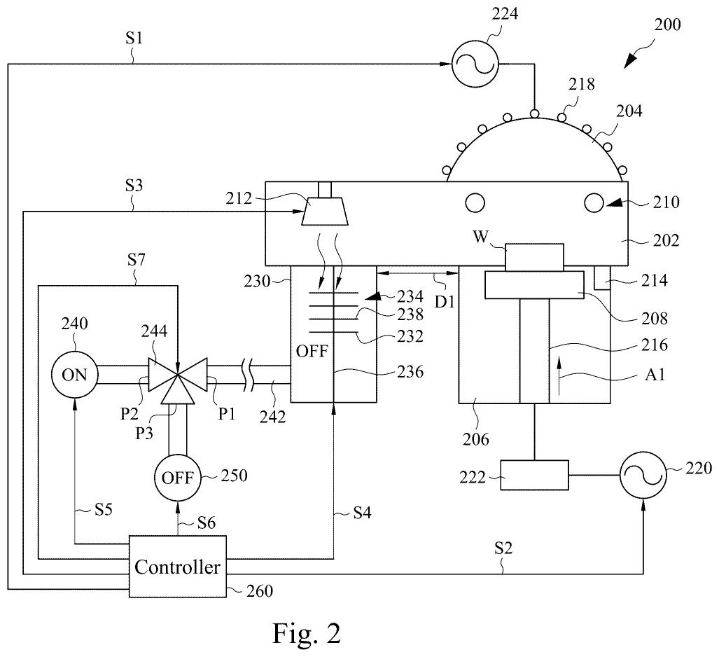

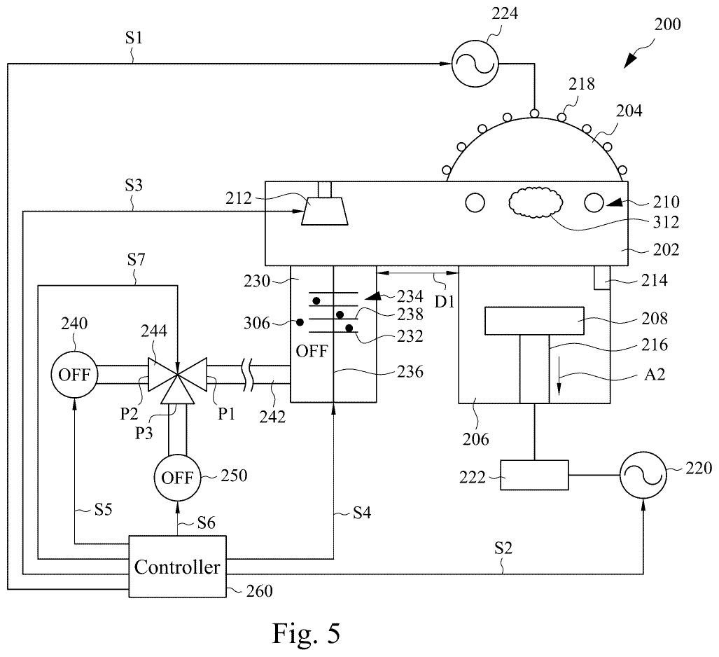

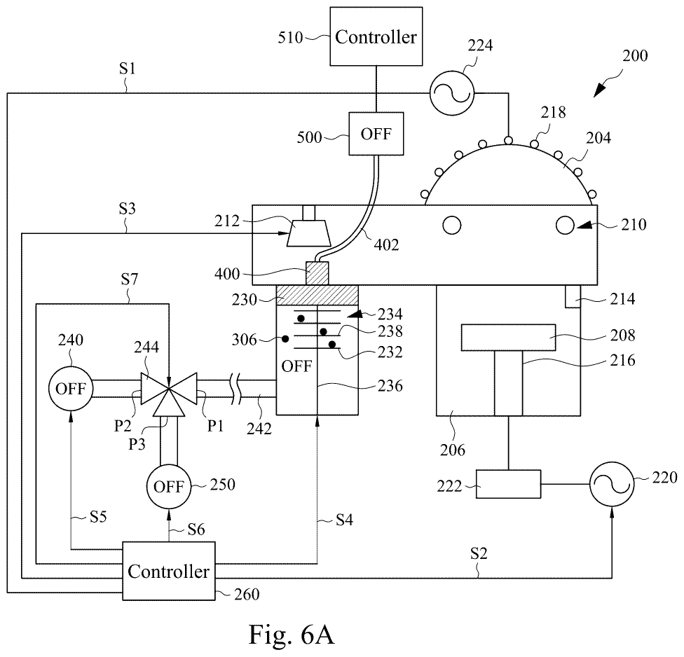

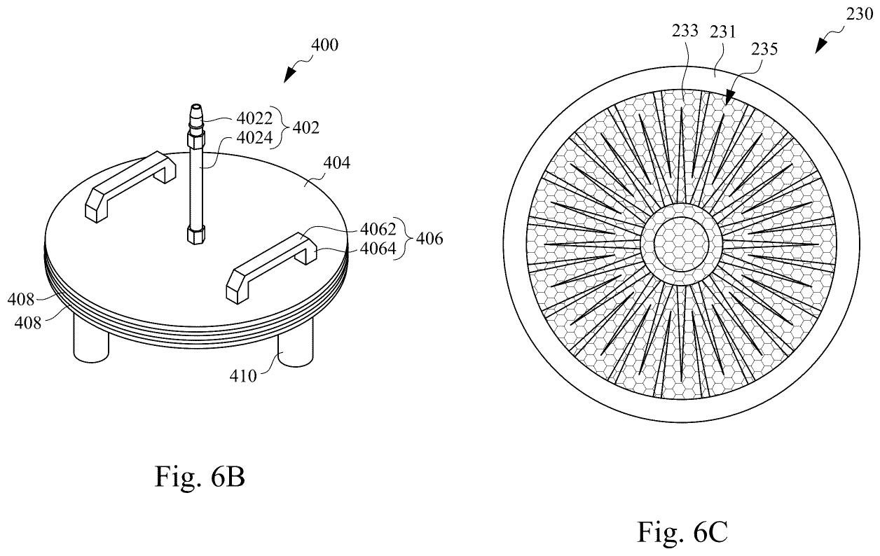

FIG. 1 is a flow chart illustrating an exemplary process 100 for plasma etching apparatus operation and maintenance, in accordance with some embodiments of the present disclosure. In operation 102, a plasma etching is performed on a wafer by using a plasma etching apparatus, which is described in detail with respect to FIGS. 2-4C. In operation 104, after one or more plasma etching operations are completed to one or more wafers, a wafer-less auto clean (WAC) operation is performed within the plasma etching apparatus, which is described in detail with respect to in FIG. 5. In operation 106, after the WAC operation is completed, a pump purging operation is performed to purge a vacuum pump within the plasma etching apparatus, which is described in detail with respect to FIGS. 6A-9B. These operations 102, 104 and 106 can collectively constitute a cyclic process that can be repeated to perform plasma etching on a large amount of wafers, with minimal impact on yield caused by the by-product particles.

FIG. 2 is a schematic side view of a plasma etching apparatus 200, illustrating an initial step of the plasma etching operation 102. The plasma etching apparatus 200 includes an upper chamber 202 having a ceramic dome 204, and a lower chamber 206. The lower chamber 206 includes an electrostatic chuck (ESC) cathode 208, also referred to as a wafer chuck 208. Gas is introduced into the chamber via gas injection nozzles 210 for uniform gas distribution. Chamber pressure is controlled by a throttle valve 212. During processing, a substrate W is loaded into the lower chamber 206 through a wafer load port 214. The substrate W is held in place by a static charge generated on the surface of electrostatic chuck (ESC) cathode 208 by applying a DC voltage to a conductive layer located under a dielectric film on the chuck surface (not shown). The ESC cathode 208 and substrate W are then raised by a wafer lift 216 (as denoted by the arrow A1) and a seal is created against the upper chamber 202 in position for processing. Etch gases are introduced into the upper chamber 202 via the ceramic gas injection nozzles 210. The plasma etching apparatus 200 uses an inductively coupled plasma power source 224 operating at about 1-3 MHZ, which is connected to inductive coil 218 for generating and sustaining a high density plasma. The wafer is biased with an RF source 220 and matching network 222 operating within the range of 50 kHz to 15 MHZ; more particular, within the range of 100 kHz to 3 MHZ. Power to the plasma power source 224 and substrate biasing RF source 220 are controlled by a controller 260.

The upper chamber 202 and the lower chamber 206 are in gaseous communication with the throttle valve 212. The throttle valve 212 is located above and in gaseous communication with a turbo molecular pump 230, which is in gaseous communication with a rough pump 240 via an exhaust pipeline 242. The turbo molecular pump 230 and the rough pump 240 are vacuum pumps that collectively serve as a vacuum source designed to achieve target pressure conditions within the chambers 202, 206 for the plasma etching process. In some embodiments, the lower chamber 206 is connected to a first region at a bottom side of the upper chamber 202, and the turbo molecular pump 230 is connected to a second region at the bottom side of the upper chamber 202. The turbo molecular pump 230 is separated from the lower chamber 206 by a non-zero horizontal distance.

In some embodiments, the turbo molecular pump 230 is a high-vacuum pump that utilizes rapidly rotating blades 232 to impart kinetic energy to gas molecules, effectively compressing and transporting them out of the chambers 202, 206 to achieve lower pressures. The turbo molecular pump 230 is well-suited for achieving high vacuum conditions, operating in the range of about 10⁻³ to 10⁻⁹ torr. The turbo molecular pump 230 operates at high rotational speeds, such as exceeding 20,000 revolutions per minute (RPM), allowing for efficient handling of large volumes of gas.

The rough pump 240, interchangeably referred to a backing dry pump, complements the turbo molecular pump 230 by managing initial and medium vacuum levels, usually from atmospheric pressure down to approximately 10⁻³ torr. In some embodiments, the rough pump 240 is a mechanical pump such as a rotary vane or scroll pump, which uses positive displacement mechanisms to evacuate gas up to a moderate vacuum level. The rough pump 240 serves to reduce the chamber pressure in the chambers 202, 206 to a level where the turbo pump 230 can effectively take over and achieve the target vacuum condition for performing the plasma etching process.

In the plasma etching operation 102, maintaining the correct vacuum level is helpful for controlling the plasma's density, composition, and uniformity, all of which affect the etch rate and pattern fidelity. The rough pump 240 first evacuates the chambers 202, 206 to a sufficient level before the turbo molecular pump 230 attains the high vacuum conditions serving for stable plasma formation. This coordinated operation allows for accurate control of process parameters such as etch selectivity, profile control, and minimal substrate damage. Consequently, the combination of these pumps 230, 240 ensures reliable and repeatable etching results.

In some embodiments, the turbo molecular pump 230 is further in gaseous communication with a purging pump 250 through the exhaust pipeline 242. The purging pump 250 serves to expel the gas from an interior space 234 of the turbo molecular pump 230 in the pump purging operation 106, thereby removing by-product particles from the interior space 234 of the turbo molecular pump 230 by using the gas flow. Given that the purging pump 250 serves for a different role than the turbo molecular pump 230 and the rough pump 240, the purging pump 250 can be a different pump than the turbo molecular pump 230 and the rough pump 240. For example, the purging pump 250 can be diaphragm pump, peristaltic pump, piston pump, or the like.

In some embodiments, the plasma etching apparatus 200 may further include a valve 244 that regulates whether the gas flows towards the rough pump 240 or flows towards the purging pump 250. In some embodiments, the valve 244 is a three-way valve, which offers control over the flow direction of the gas flow pumped out from the turbo molecular pump 230. For example, the three-way valve 244 operates by providing three ports, which include an inlet port P1 and two outlet ports P2 and P3. The inlet port P1 of the three-way valve 244 receives the gas flow from the turbo molecular pump 230. The first outlet port P2 of the three-way valve 244 directs the gas flow to the rough pump 240. The second outlet port P3 of the three-way valve 244 directs the gas flow to the purging pump 250.

In some embodiments, the plasma etching apparatus further includes a controller 260 in communication with the plasma power source 224, the substrate biasing RF source 220, the throttle valve 212, the turbo molecular pump 230, the rough pump 240, the purging pump 250, and the three-way valve 244. For example, the controller can generate a control signal S1 to the plasma power source 224, a control signal S2 to the substrate biasing RF source 220, a control signal S3 to the throttle valve 212, a control signal S4 the turbo molecular pump 230, a control signal S5 to the rough pump 240, a control signal S6 to the purging pump 250, and a control signal S7 the three-way valve 244. These control signals S1-S7 are used to manage the operations of the plasma power source 224, the substrate biasing RF source 220, the throttle valve 212, the turbo molecular pump 230, the rough pump 240, the purging pump 250, and the three-way valve 244, which will be described in greater detail below.

In some embodiments, the controller 260 may include a central processing unit (CPU), a memory unit, and a support circuit utilized to control the process sequence and regulate the gas flows and plasma process performed in the plasma etching apparatus 200. The CPU may be of any form of a general purpose computer processor that may be used in an industrial setting. The software routines such as the etching process described below can be stored in the memory unit, such as random access memory, read only memory, floppy, or hard disk drive, or other form of digital storage. The support circuit is coupled to the CPU and may include cache, clock circuits, input/output systems, power supplies, and the like. Bi-directional communications between the controller 260 and the various components of the plasma etching apparatus 200 are handled through numerous signal cables that serve to transmit the control signals S1-S7.

At the initial step of plasma etching operation 102, as illustrated in FIG. 2, the rough pump 240 is activated, as denoted by the “ON” label in FIG. 2, initiating evacuating the chambers 202, 206 from atmospheric pressure down to a first pressure level (e.g., about 10⁻² torr-10⁻³ torr). During this step, the turbo pump 230 remains deactivated or remains in the “OFF” state, as denoted by the “OFF” label illustrated in the turbo pump 230 FIG. 2. Once the rough pump 240 is activated, gas is drawn from the chambers 202, 206, and the interior space 234 of the turbo molecular pump 230. In some embodiments, the rough pump 240 is activated in response to the control signal S5 from the controller 260, and the turbo molecular pump 230 remains deactivated in response to the control signal S4 from the controller 260.

In some embodiments, the rough pump 240 which is a mechanical pump such as a rotary vane or a scroll pump, operates by creating a pressure differential that draws gas molecules out of the chambers 202, 206 and the interior space 234 of the turbo molecular pump 230. This process begins with the rotor of the rough pump 240, which is eccentrically mounted within a stator. As the rotor turns, it traps gas molecules in the spaces between the vanes and the stator wall. The rotation of the rotor decreases the volume of these spaces, compressing the gas and pushing it towards the exhaust port. This continuous cycle of trapping, compressing, and expelling gas molecules effectively reduces the pressure within the chambers 202, 206, and the interior space 234 of the turbo molecular pump 230 from atmospheric pressure down to first pressure level (e.g., about 10⁻² torr-10⁻³ torr). The rough pump 240 is designed to handle relatively high gas loads and is robust enough to manage the initial evacuation from atmospheric pressure. Once the rough pump 240 has sufficiently lowered the pressure in the chambers 202, 206, it creates an environment suitable for the activation of the turbo pump 230. The rough pump's ability to handle large volumes of gas quickly facilitates the initial stage of the plasma etching operation 102, setting the stage for the more precise and high-vacuum capabilities of the turbo pump 230 that follow.

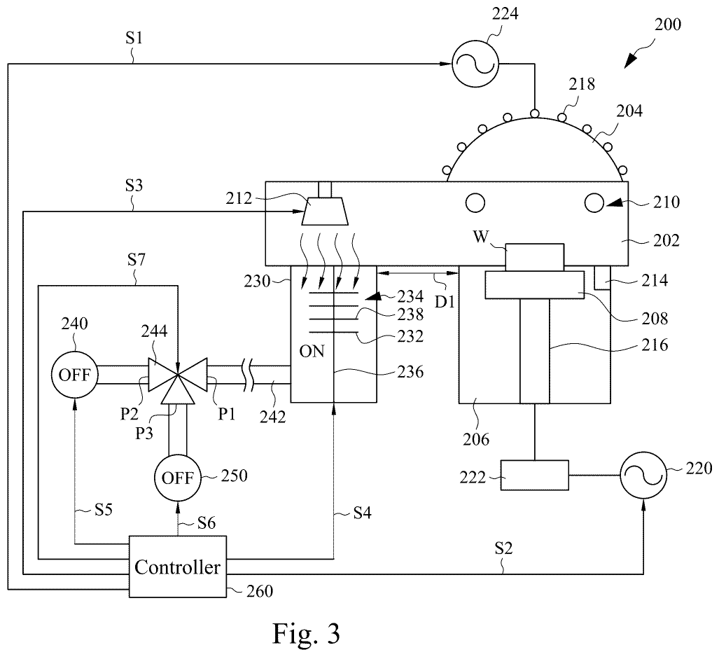

In FIG. 3, after the rough pump 240 has reduced the pressure within the chambers 202, 206, and the interior space 234 of the turbo molecular pump 230 from atmospheric pressure down to the first pressure level (e.g., about 10⁻² torr-10⁻³ torr), the turbo molecular pump 230 is activated, as denoted by the “ON” label in FIG. 3. This activation evacuates the chambers 202, 206 from the first pressure level down to a second pressure level (e.g., about 10⁻⁸ torr-10⁻⁹ torr) which is lower than the first pressure level by a plurality of orders of magnitude. In some embodiments, the turbo molecular pump 230 is activated in response to the control signal S4 from the controller 260, and the rough pump 240 may be deactivated in response to the control signal S4 from the controller 260. In some embodiments, the rough pump 240 is deactivated after activating the turbo molecular pump 230. In some other embodiments, the rough pump 240 remains activated after activating the turbo molecular pump 230.

In some embodiments, the turbo molecular pump 230 operates by utilizing a series of rapidly rotating rotor blades 232, which are mounted on a rotor 236, and stationary stator blades 238 that are stationary with respect to the rotor blades 232. These blades 232, 238 serve to interact with gas molecules within the turbo molecular pump 230. As the rotor 236 spins at high speeds, e.g., exceeding 20,000 revolutions per minute (RPM), the angled blades impart momentum to the gas molecules, effectively directing them towards the exhaust pipeline 242, which is gaseous downstream of the turbo molecular pump 230. In some embodiments, the rotor blades 232 are arranged in multiple elevations, with each elevation progressively reducing the pressure. The rotor blades 232 can be made from lightweight, high-strength materials such as titanium or aluminum alloys, which allow for high-speed rotation without significant wear or deformation. The stator blades 238, alternating with the rotor blades 238, are fixed and serve to redirect the gas molecules back towards the rotor 236, enhancing the efficiency of the pumping process.

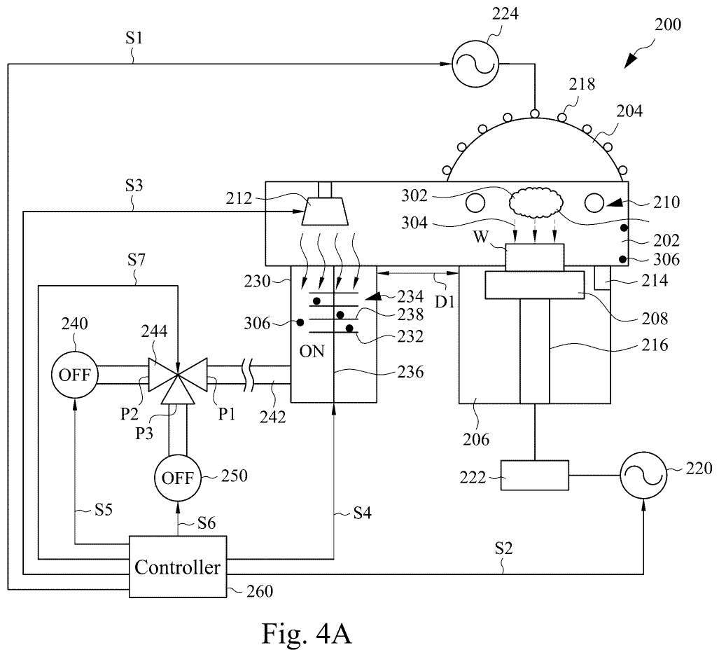

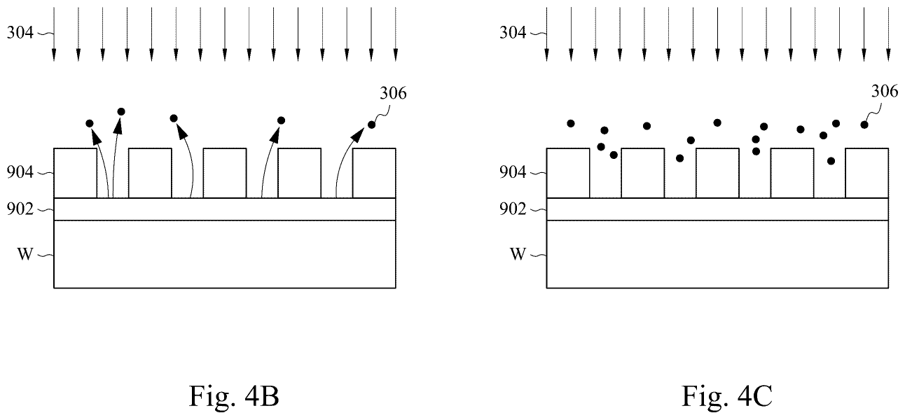

In FIG. 4A, after the turbo molecular pump 230 has reduced the pressure within the chambers 202, 206 from the first pressure level (e.g., about 10⁻² torr-10⁻³ torr) to the second pressure level (e.g., about 10⁻⁸ torr-10⁻⁹ torr), the plasma power source 224 is activated by the control signal S1 from the controller 260, allowing the inductive coil 218 for generating and sustaining an etching plasma 302 in the upper chamber 202. When activated, the plasma power source 224 supplies radio frequency (RF) energy to the inductive coil 218, which is configured as a helical or planar coil surrounding the ceramic chamber dome 204. This RF energy induces an oscillating electromagnetic field within the upper chamber 202, which in turn ionizes the process gas introduced into the upper chamber 202 through the gas injection nozzles 210, creating a plasma 302 in the upper chamber 202. The high energy electrons within the plasma collide with neutral gas molecules, sustaining the ionization process and maintaining a stable plasma environment. The frequency of the RF energy may be in the range of about 13.56 MHz, although other frequencies may be used depending on the specific process requirements and chamber design.

In some embodiments, the substrate biasing RF source 220 is also activated by the control signal S2 from the controller 260, which enhances the control over the ion energy impacting the substrate W. The substrate biasing RF source 220 applies a separate RF voltage to the electrostatic chuck cathode 208, creating a bias potential that attracts ions 304 from the plasma 302 towards the substrate W. This biasing allows for precise control over the ion energy and directionality, which allows for anisotropic etching processes where vertical etching rate is faster than the horizontal etching rate. The biasing RF source may operate at a different frequency than the plasma power source 224, such as in the range of 300 kHz to 2.5 MHz, to allow independent control of ion energy and plasma density.

FIGS. 4B and 4C are cross-sectional views zoomed-in to the substrate W, respectively illustrating an initial stage and a final stage of the plasma etching operation 102. In FIG. 4B, an etching target layer 902 is formed over the substrate W, and a patterned mask layer 904 is formed over the etching target layer 902. In some embodiments, the substrate W may be a semiconductor substrate, such as a bulk semiconductor, a semiconductor-on-insulator (SOI) substrate, or the like, which may be doped (e.g., with a p-type or an n-type dopant) or undoped. The substrate W may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate W may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, the etching target layer 902 may be a metal layer, for example, a copper layer, a silver layer, a gold layer, or other metal layers, or combinations thereof. In some embodiments, the etching target layer 902 may be a dielectric layer, such as a silicon oxide layer, a silicon nitride layer, a silicon oxynitride layer, other dielectric layer, or combinations thereof. In some embodiments, the etching target layer 902 is a polysilicon layer. In some embodiments, the patterned mask layer 904 is a photoresist layer, which is coated on the etching target layer 902 by using a spin-on coating technique, followed by patterning the photoresist layer using acceptable photolithography techniques. The plasma ions 304 etch away portions of the etching target layer 902 exposed by openings of the patterned mask layer 904. As the plasma ions 304 etch away portions of the etching target layer 902, a large amount of by-product particles 306 (e.g., toxic particles such as chlorine-containing or fluorine-containing particles) is generated and accumulates on the chamber walls in the upper chamber 202, on the blades 232, 238 of the turbo molecular pump 230, and in the interior space 234 of the turbo molecular pump 230. In some embodiments, the by-product particles 306 may be non-volatile by-product particles. Therefore, as the etching target layer 902 on this substrate W (or subsequent substrates) continues to be etched, these by-product particles 306 may detach from chamber walls in the upper chamber 202 or detach from blades 232, 238 of the turbo molecular pump 230, thus contaminating this substrate W or subsequent substrates.

Therefore, after one or more plasma etching operations 102 have been performed on one or more substrates W, the wafer-less auto clean (WAC) operation 104 is performed. As illustrated in FIG. 5, after completing a plasma etching operation 102 on the last substrate W, this substrate W is unloaded from the plasma etching apparatus 200 through the wafer load port 214. In some embodiments, the ESC cathode 208 can be lowered by the wafer lift 216 (as denoted by the arrow A2) after completing the plasma etching operation 102. After retreating the last substrate W from the plasma etching apparatus 200, the WAC operation is performed by a cleaning plasma 312 to remove the by-product particles 306 from walls of the upper chamber 202.

For example, after the completion of plasma etching operations on a batch of substrates W, the turbo molecular pump 230, the rough pump 240, the purging pump 250, the plasma power source 224, and the substrate biasing RF source 220 are deactivated. Next, the inductively coupled plasma power source 224 is reactivated in response to the control signal S1 from the controller 260, without any substrate W accommodated in the plasma etching apparatus 200. This activation energizes the inductive coil 218 to generate a cleaning plasma 312 within the upper chamber 202. In some embodiments, the cleaning plasma 312 can be formed from a different gas chemistry than the etching plasma 302 used during the plasma etching operation 102. For example, the cleaning plasma 312 includes reactive species such as oxygen (O₂), fluorine (F₂), or chlorine (Cl₂), depending on the nature of the by-product particles 306 to be removed. These reactive species are chosen for their ability to chemically react with and volatilize the by-product particles 306, effectively cleaning the chamber surfaces. The cleaning plasma 312 is sustained for a predetermined duration, during which the reactive species interact with the by-product particles 306, breaking them down into volatile compounds that may be subsequently evacuated from the upper chamber 202 by the purging pump 250.

In some embodiments, the WAC operation may be enhanced by the application of a bias voltage to the ESC cathode 208, similar to the substrate biasing during etching operations. This biasing can help direct the reactive ions towards specific areas of the chambers 202 and 206, improving the efficiency of the cleaning process. Additionally, the wafer lift 216 may be used to adjust the position of the ESC cathode 208, allowing for better access to areas that are prone to by-product buildup.

While the cleaning plasma 312 is effective at removing by-product particles 306 from the walls of chambers 202 and 206, reaching the interior space 234 of the turbo molecular pump 230 presents a challenge. The primary reason for this difficulty is the horizontal distance D1, which is approximately 40 cm or longer, between the inductive coil 218 and the turbo molecular pump 230, or between the lower chamber 206 and the turbo molecular pump 230. This significant separation limits the ability of the cleaning plasma 312 to penetrate and effectively clean the interior space 234 of the turbo molecular pump 230. In particular, the cleaning plasma 312 relies on the proximity of the inductive coil 218 to generate and sustain reactive species that can interact with and remove the by-product particles. However, as the horizontal distance D1 from the inductive coil 218 increases, the density and reactivity of the plasma diminish, reducing its effectiveness in reaching and cleaning remote areas such as the interior space 234 of the turbo molecular pump 230.

Therefore, after performing the WAC operation 104, a pump purging operation 106 is performed. FIG. 6A is a side view illustrating an initial step of the pump purging operation 106. FIG. 6B is a three-dimensional view of the pneumatic purging apparatus 400, and FIG. 6C is a top view of the turbo molecular pump 230, in accordance with some embodiments of the present disclosure. At the initial step of the pump purging operation 106, a pneumatic purging apparatus 400 is placed onto the turbo molecular pump 230.

The pneumatic purging apparatus 400 is designed to facilitate the effective removal of by-product particles 306 from the interior space 234 and the blades 232, 238 of the turbo molecular pump 230, by using a continuous gas flow. The gas flow introduced through the pneumatic purging apparatus 400 is expelled from the turbo molecular pump 230 via the exhaust pipeline 242, ensuring that the unwanted by-product particles 306 are removed efficiently.

As illustrated in FIG. 6B, in some embodiments, the pneumatic purging apparatus 400 includes a purging gas inlet pipe 402 and a sealing cover 404. The gas inlet pipe 402 is positioned centrally on a top surface of the sealing cover 404. The gas inlet pipe 402 serves as a conduit for introducing a continuous flow of compressed dry air (CDA) or other purging gases, such as nitrogen (N₂) gas, into the turbo molecular pump 230. This gas flow assists in loosening and removing by-product particles 306 that may adhere to blades 232, 238 or other internal surfaces of the turbo molecular pump 230. The gas inlet pipe 402 is dimensioned to allow a precise and controlled flow rate of CDA, ensuring that by-product particles 306 within the turbo molecular pump 230 are continuously purged. The placement of the gas inlet pipe 402 on the center region of the top surface of the sealing cover 404 facilitates even distribution of the purging gas into the turbo molecular pump 230, enhancing the purging effect. Once introduced into the turbo molecular pump 230, the gas flow creates a dynamic environment that drives the by-product particles 306 towards the exhaust pipeline 242 connected to the turbo molecular pump 230. This exhaust pipeline 242 continuously evacuates the gas along with the entrained particles 306, thereby removing the by-product particles 306 from the turbo molecular pump 230. In some embodiments, the gas inlet pipe 402 includes an intake nozzle 4022 serving for connect to an external purging gas source 500 (e.g., CDA source) via a threaded or quick-release connector, and a flexible hose 4024 connecting the intake nozzle 4022 to a gas inlet opening on the top surface of the sealing cover 404.

As illustrated in FIG. 6B, in some embodiments, the sealing cover 404 is a disk-shaped plate configured to be placed over the upper opening of the turbo molecular pump 230, enclosing the interior space 234 of the turbo molecular pump 230. The sealing cover 404 has a substantially flat top surface where the gas inlet pipe 402 and handles 406 are integrated or mounted. The diameter of the sealing cover 404 is dimensioned to match the opening 235 defined by the top rim 231 of the turbo molecular pump 230, ensuring proper alignment during installation.

The sealing cover 404 cooperates with double seal O-rings 408 to form an airtight connection with the top rim 231 of the turbo molecular pump 230. In some embodiments, the sealing cover 404 may be fabricated from a material such as stainless steel or an aluminum alloy to withstand operational stress and environmental exposure, ensuring long-term reliability. The sealing cover 404 also provides mechanical support to the other components, such as handles 406 and brackets 410, allowing the pneumatic purging apparatus 400 to be securely mounted to the turbo molecular pump 230.

In some embodiments, as illustrated in FIG. 6B the pneumatic purging apparatus 400 further includes two handles 406 attached to or integrally formed with the top surface of the sealing cover 404. These handles 406 are spaced apart to allow for convenient manual handling. Each handle 406 is shaped to accommodate an operator's grip, facilitating easy lifting, placement, and removal of the pneumatic purging apparatus 400. In some embodiments, each handle 406 includes a main portion 4062 extending parallel with the top surface of the sealing cover 404, and two supporting portions 4064 extending from opposite ends of the main portion 4062 to the top surface of the sealing cover 404. During installation, the operator uses the handles 406 to align the sealing cover 404 with the top rim 231 of the turbo molecular pump 230, ensuring a secure and precise fit.

The ergonomic configuration of the handles 406 ensures that minimal force is used for assembly and disassembly, reducing the risk of damaging the O-rings 408 or disturbing the sealed connection between the sealing cover 404 and top rim 231 of the turbo molecular pump 230. The handles 406 may be made of the same material as the sealing cover 404, or they may include a different material than the sealing cover 404. For example, the handles 406 may include non-slip grips for better usability during operation in a controlled environment such as a semiconductor fabrication facility.

In some embodiments, the sealing mechanism of the pneumatic purging apparatus 400 includes double seal O-rings 408, which are tightly fitted around separate regions on a circumferential wall of the sealing cover 404. For example, one O-ring 408 is tightly fitted around an upper region on the circumferential wall of the sealing cover 404, and another O-ring 408 is tightly fitted around a lower region on the circumferential wall of the sealing cover 404. These O-rings 408 are configured to engage with the top rim 231 of the turbo molecular pump 230, providing an airtight seal. The dual O-rings 408 are designed to form a redundant seal, ensuring that even if one O-ring 408 becomes compromised due to surface imperfections or wear, the other O-ring 408 will maintain the integrity of the connection.

The O-rings 408 comprise materials such as nitrile rubber, selected for their chemical resistance, durability, and ability to maintain elasticity under varying temperatures and pressure conditions. The double-seal design compensates for potential misalignment or small surface irregularities between the sealing cover 404 and the top rim 231 of the turbo molecular pump 230, providing a reliable and consistent seal to prevent the by-product particles 306 from moving into the chambers 202, 206.

In some embodiments, the pneumatic purging apparatus 400 further includes brackets 410 extending downwards from the bottom surface of the sealing cover 404. These brackets 410 are configured to rest on a perforated cover 233 located above of blades 232, 238 of the turbo molecular pump 230. The brackets 410 act as stabilizing supports, ensuring that the sealing cover 404 remains properly positioned and aligned during operation. In some embodiments, the brackets 410 are cylindrical brackets.

The brackets 410 also provide clearance for the interior space 234 of the turbo molecular pump 230 below the perforated cover 233, ensuring that airflow is not obstructed and that the CDA introduced through the gas inlet pipe 402 can circulate freely within the interior space 234 of the turbo molecular pump 230.

In the initial step of the pump purging operation 106, as depicted in FIGS. 6A-6C, the operator aligns the circumferential wall of the sealing cover 404 with the top rim 231 of the turbo molecular pump 230. This alignment is facilitated by the handles 406, which provide guidance and control. The operator then lowers the sealing cover 404 onto the top rim 231 of the turbo molecular pump 230, such that the double seal O-rings 408 are compressed against the ring-shaped top rim 231 of the turbo molecular pump 230. This compression creates an airtight seal, effectively preventing any by-product particles 306 from entering the chambers 202 and 206. Once the brackets 410 make contact with the perforated cover 233 of the turbo molecular pump 230, the operator halts the downward movement of the sealing cover 404. The brackets 410 rest on the perforated cover 233, offering additional support and helping that the sealing cover 404 remains securely positioned above the perforated cover 233.

In some embodiments, in the initial step of the pump purging operation 106, the turbo molecular pump 230, the rough pump 240, the purging pump 250 remain deactivated by the control signals S4, S5, and S6. The external purging gas source 500 also remains deactivated by an external controller 510.

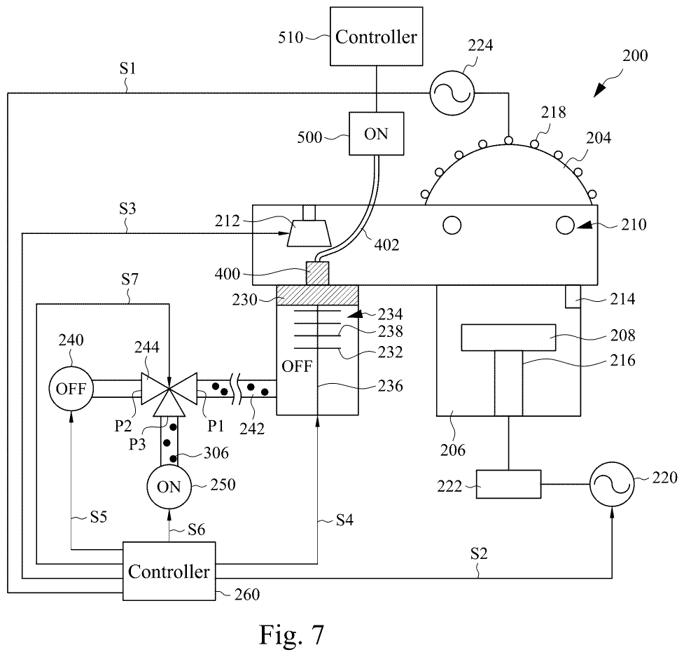

Once the pneumatic purging apparatus 400 is assembled onto the turbo molecular pump 230, in the next step of the pump purging operation 106 as illustrated in FIG. 7, compressed dry air (CDA) or another purging gas is introduced through the gas inlet pipe 402. The gas flow enters the turbo molecular pump 230 and circulates within the interior space 234 of the turbo molecular pump 230, dislodging and blowing away the etching by-product particles 306 that have accumulated on the surfaces in the interior space 234 and blades 232, 238. The flow of gas drives these particles 306 towards the exhaust pipeline 242 connected to the turbo molecular pump 230, where they are expelled from the turbo molecular pump 230 along with the gas flow. The continuous purging of by-product particles 306 prevents the buildup of contaminants within the turbo molecular pump 230. This ensures the plasma etching apparatus 200 operates efficiently, with minimal downtime for cleaning or maintenance.

In some embodiments, the purging pump 250 can be activated in response to the control signal S6 from the controller 260, so as to draw the purging gas flow and the by-product particles 306 entrained in the purging gas flow away from the exhaust pipe 242. In some embodiments, the controller 260 can manage the operation of the three-way valve 244 by sending the control signals S7, such as control voltages, to switch the open/closed position of each port of the three-way valve 244, enabling the purging pump 250 to be in gaseous communication with the exhaust pipe 242. For example, the three-way valve 244 can be switched to have a closed position on the first outlet port P2 and an open position on the second outlet port P3, allowing the purging gas flow and the by-product particles 306 entrained in the purging gas flow to be drawn by the purging pump 250.

After the pump purging operation 106 is completed to remove the by-product particles 306 from the turbo molecular pump 230, the purging pump 250 and the purging gas source 500 are deactivated by the controllers 260, 510, respectively. Next, the operator can use the handles 406 to disassemble the pneumatic purging apparatus 400 from the turbo molecular pump 230. The modular design of the pneumatic purging apparatus 400 allows for quickly assembled on the turbo molecular pump 230 or disassembled from the pneumatic purging apparatus 400, minimizing downtime for the pump purging operation 106.

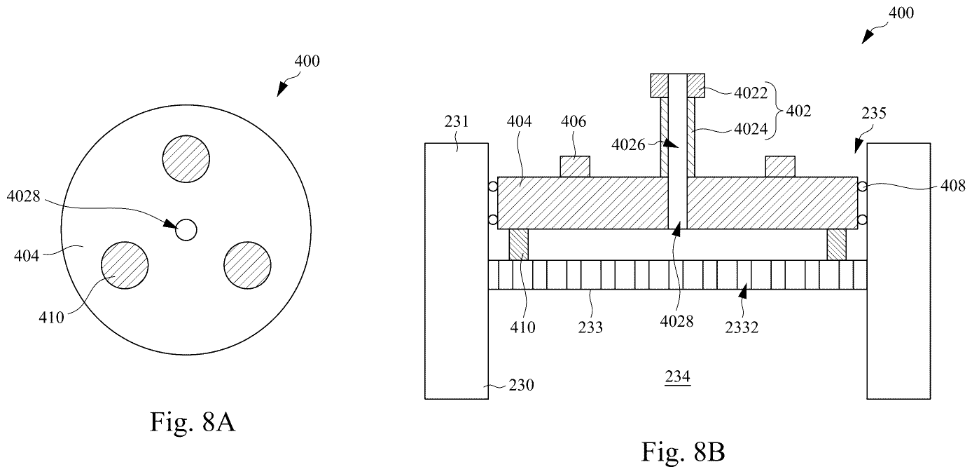

FIG. 8A illustrates a bottom view of the pneumatic purging apparatus 400, and FIG. 8B illustrates a zoomed-in cross-sectional view at a region where the pneumatic purging apparatus 400 has been assembled onto the turbo molecular pump 230, in accordance with some embodiments of the present disclosure. In some embodiments, the gas inlet pipe 402 has a gas channel 4026 extending through the intake nozzle 4022, the flexible hose 4024, the top surface of the sealing cover 404, and the bottom surface of the sealing cover 404. The gas channel 4026 terminates at a gas exit 4028, which is located at a center region of the bottom surface of the sealing cover 404. This is where the purging gas exits the pneumatic purging apparatus 400 after traveling through the gas channel 4026. The brackets 410 extend downwards from the bottom surface of the sealing cover 404, and the handles 406 extend upwards from the top surface of the sealing cover 404.

As illustrated in FIG. 8B, when the pneumatic purging device 400 is placed onto the turbo molecular pump 230, the sealing cover 404 will be accommodated within the opening 235 defined by the ring-shaped top rim 231 of the turbo molecular pump 230. Moreover, the double seal O-rings 408 are compressed against the rim-shaped top rim 231, forming an airtight seal with the rim-shaped top rim 231. In such scenarios, the double seal O-rings 408 may undergo elastic deformation, resulting in an elliptical cross-section having a vertically-extending major axis (i.e., the long axis) and a horizontally-extending minor axis (i.e., the short axis, which is shorter than the major axis), caused by the horizontal compression forces exerted by the ring-shaped top rim 231. The pneumatic purging apparatus 400 can eject a purging gas through the gas exit 4028 at the bottom surface of the sealing cover 404. The ejected purging gas can flow into the interior space 234 of the turbo molecular pump 230 through the openings 2332 in the perforated cover 233.

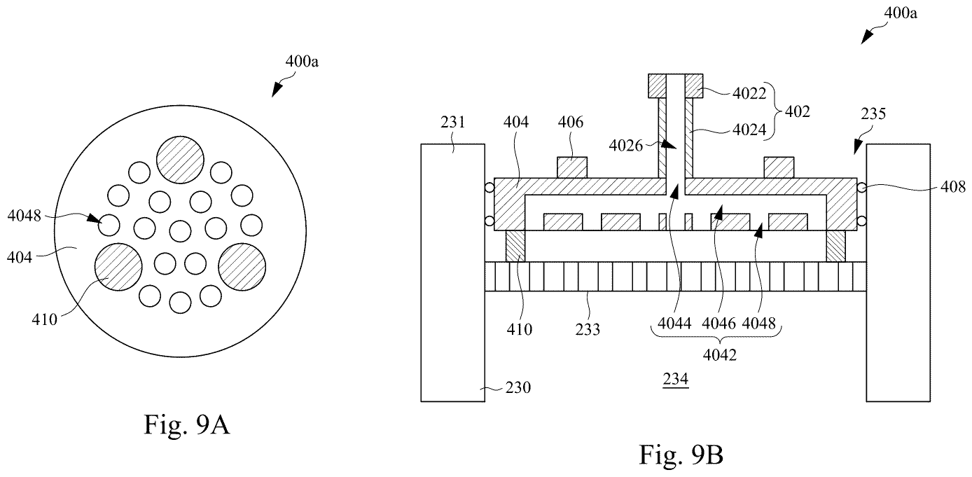

FIG. 9A illustrates a bottom view of a pneumatic purging apparatus 400a, and FIG. 8B illustrates a zoomed-in cross-sectional view at a region where the pneumatic purging apparatus 400a has been assembled onto the turbo molecular pump 230, in accordance with some embodiments of the present disclosure. The pneumatic purging apparatus 400a is substantially the same as the pneumatic purging apparatus 400, except that the pneumatic purging apparatus 400a includes a manifold 4042 within the sealing cover 404 for gas distribution within the sealing cover 404. In some embodiments, the manifold 4042 includes an inlet port 4044 at the top surface of the sealing cover 404 and in gaseous communication with the gas channel 4026 in the gas inlet pipe 402, allowing the purging gas to enter the manifold 4042 from the gas inlet pipe 402. The manifold 4042 further includes a main channel 4046 with an elongated shape extending in a direction substantially parallel with the top surface of the sealing cover 404, allowing for even distribution of the purging gas cross the manifold 4042. The manifold 4042 further includes multiple outlet ports 4048 located at the bottom surface of the sealing cover 404. These outlet ports 4048 serve as multiple gas exits, allowing the purging gas to be distributed evenly across the area beneath the sealing cover 404.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is the efficient removal of etching by-product particles from the turbo molecular pump by using the pneumatic purging apparatus. For instance, when the plasma etching apparatus is cleaned solely using the wafer-less clean operation, the failure rate of these cleaning operations ranges from approximately 12% to 16%. This means that about 12% to 16% of the cleaning operations result in particle counts exceeding the acceptable threshold within the plasma etching apparatus. However, when the cleaning process includes both the wafer-less clean operation and the subsequent pneumatic purging operation, the failure rate can be significantly reduced to below approximately 6%. Consequently, the pneumatic purging operation can significantly improve the cleanliness of the plasma etching apparatus.

In some embodiments, a method includes reducing a pressure within a chamber from a first pressure level to a second pressure level using a first pump; after reducing the pressure within the chamber to the second pressure level, performing a plasma etching operation in the chamber; after performing the plasma etching operation, placing a pneumatic purging apparatus onto the first pump; and after placing the pneumatic purging apparatus onto the first pump, purging an interior space of the first pump by ejecting a purging gas from the pneumatic purging apparatus. In some embodiments, placing the pneumatic purging apparatus onto the first pump comprises lowering the pneumatic purging apparatus such that an O-ring of the pneumatic purging apparatus forms an airtight seal with a top rim of the first pump. In some embodiments, placing the pneumatic purging apparatus onto the first pump comprises moving the pneumatic purging apparatus using two handles on a sealing cover of the pneumatic purging apparatus. In some embodiments, placing the pneumatic purging apparatus onto the first pump comprises moving a sealing cover of the pneumatic purging apparatus into an opening defined by a top rim of the first pump. In some embodiments, placing the pneumatic purging apparatus onto the first pump comprises lowering a sealing cover of the pneumatic purging apparatus until brackets extending downwards from the sealing cover reach a perforated cover of the first pump. In some embodiments, purging the interior space of the first pump comprises activating a gas source in gaseous communication with a gas inlet pipe extending upwards from a sealing cover of the pneumatic purging apparatus. In some embodiments, the gas source is a compressed dry air (CDA) source. In some embodiments, the gas inlet pipe comprises an intake nozzle and a flexible hose connecting the intake nozzle to the sealing cover. In some embodiments, the first pump is a turbo molecular pump. In some embodiments, the method further includes activating a second pump to draw the purging gas away from the interior space of the first pump through an exhaust pipeline in gaseous communication with the interior space of the first pump. In some embodiments, the first pump remains deactivated after activating the second pump.

In some embodiments, a method includes loading a substrate into a plasma etching apparatus; performing a plasma etching process on the substrate by using a first plasma generated within the plasma etching apparatus, wherein by-product particles are formed in the plasma etching process; after performing the plasma etching process, unloading the substrate from the plasma etching apparatus; after unloading the substrate, cleaning a chamber of the plasma etching apparatus by using a second plasma; and blowing the by-product particles away from blades of a pump of the plasma etching apparatus. In some embodiments, blowing the by-product particles away from the blades of the pump of the plasma etching apparatus is performed after cleaning the chamber of the plasma etching apparatus using the second plasma. In some embodiments, blowing the by-product particles is performed by using a pneumatic purging apparatus. In some embodiments, the method further includes placing the pneumatic purging apparatus onto the pump prior to blowing the by-product particles. In some embodiments, placing the pneumatic purging apparatus onto the pump comprises lowering a sealing cover of the pneumatic purging apparatus such that an O-ring around a circumferential wall of the sealing cover is compressed against a ring-shape top rim of the pump.

In some embodiments, a plasma etching apparatus includes a chamber, an inductive coil over the chamber, a plasma power source electrically connected to the inductive coil, a pump in gaseous communication with the chamber and laterally distanced from the inductive coil, and a pneumatic purging apparatus operable to purge the pump. In some embodiments, the pneumatic purging apparatus comprises a sealing cover accommodated within an opening defined by a top rim of the pump when the pneumatic purging apparatus is placed onto the pump. In some embodiments, the pneumatic purging apparatus further comprises a gas inlet pipe extending upwards from a top surface of the sealing cover, and a gas channel extending through the gas inlet pipe, the top surface of the sealing cover, and a bottom surface of the sealing cover. In some embodiments, the pneumatic purging apparatus further comprises an O-ring around a circumferential wall of the sealing cover.

In some embodiments, a plasma etching apparatus includes an upper chamber, a plasma power source operable to generate a plasma in the upper chamber, a lower chamber connected to a first region of the upper chamber, a wafer chuck in the lower chamber, and a pump connected to a second region of the upper chamber. The pump is separated from the lower chamber by a non-zero horizontal distance. The plasma etching apparatus further includes a pneumatic purging apparatus, which includes a sealing cover having a gas channel extending through a top surface of the sealing cover and a bottom surface of the sealing cover, a first O-ring surrounding a circumferential wall of the sealing cover and capable of forming an airtight seal with a ring-shaped top rim of the pump, and a gas inlet pipe over the top surface of the sealing cover. The gas inlet pipe is upstream of the gas channel of the sealing cover. In some embodiments, the pneumatic purging apparatus further comprises a second O-ring surrounding the circumferential wall of the sealing cover. The second O-ring is at a higher elevation than the first O-ring. In some embodiments, the pneumatic purging apparatus further comprises two handles at opposite sides of the flexible hose. In some embodiments, the pneumatic purging apparatus further comprises a plurality of brackets extending from the bottom surface of the sealing cover.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
reducing a pressure within a chamber from a first pressure level to a second pressure level using a first pump;
after reducing the pressure within the chamber to the second pressure level, performing a plasma etching operation in the chamber;
after performing the plasma etching operation, placing a pneumatic purging apparatus onto the first pump; and
after placing the pneumatic purging apparatus onto the first pump, purging an interior space of the first pump by ejecting a purging gas from the pneumatic purging apparatus.

2. The method of claim 1, wherein placing the pneumatic purging apparatus onto the first pump comprises lowering the pneumatic purging apparatus such that an O-ring of the pneumatic purging apparatus forms an airtight seal with a top rim of the first pump.

3. The method of claim 1, wherein placing the pneumatic purging apparatus onto the first pump comprises moving the pneumatic purging apparatus using two handles on a sealing cover of the pneumatic purging apparatus.

4. The method of claim 1, wherein placing the pneumatic purging apparatus onto the first pump comprises moving a sealing cover of the pneumatic purging apparatus into an opening defined by a top rim of the first pump.

5. The method of claim 1, wherein placing the pneumatic purging apparatus onto the first pump comprises lowering a sealing cover of the pneumatic purging apparatus until brackets extending downwards from the sealing cover reach a perforated cover of the first pump.

6. The method of claim 1, wherein purging the interior space of the first pump comprises activating a gas source in gaseous communication with a gas inlet pipe extending upwards from a sealing cover of the pneumatic purging apparatus.

7. The method of claim 6, wherein the gas source is a compressed dry air (CDA) source.

8. The method of claim 6, wherein the gas inlet pipe comprises an intake nozzle and a flexible hose connecting the intake nozzle to the sealing cover.

9. The method of claim 1, wherein the first pump is a turbo molecular pump.

10. The method of claim 1, further comprising:
activating a second pump to draw the purging gas away from the interior space of the first pump through an exhaust pipeline in gaseous communication with the interior space of the first pump.

11. The method of claim 10, wherein the first pump remains deactivated after activating the second pump.

12. A plasma etching apparatus, comprising:
a chamber;
an inductive coil over the chamber;
a plasma power source electrically connected to the inductive coil;
a pump in gaseous communication with the chamber and laterally distanced from the inductive coil; and
a pneumatic purging apparatus operable to purge the pump.

13. The plasma etching apparatus of claim 12, wherein the pneumatic purging apparatus comprises a sealing cover accommodated within an opening defined by a top rim of the pump when the pneumatic purging apparatus is placed onto the pump.

14. The plasma etching apparatus of claim 13, wherein the pneumatic purging apparatus further comprises:
a gas inlet pipe extending upwards from a top surface of the sealing cover; and
a gas channel extending through the gas inlet pipe, the top surface of the sealing cover, and a bottom surface of the sealing cover.

15. The plasma etching apparatus of claim 14, wherein the gas inlet pipe comprises a flexible hose.

16. The plasma etching apparatus of claim 13, wherein the pneumatic purging apparatus further comprises:
an O-ring around a circumferential wall of the sealing cover.

17. A plasma etching apparatus, comprising:
an upper chamber;
a plasma power source operable to generate a plasma in the upper chamber;
a lower chamber connected to a first region of the upper chamber;
a wafer chuck in the lower chamber;
a pump connected to a second region of the upper chamber, the pump being separated from the lower chamber by a non-zero horizontal distance; and
a pneumatic purging apparatus comprising:
a sealing cover having a gas channel extending through a top surface of the sealing cover and a bottom surface of the sealing cover;
a first O-ring surrounding a circumferential wall of the sealing cover, the first O-ring capable of forming an airtight seal with a ring-shaped top rim of the pump; and
a gas inlet pipe over the top surface of the sealing cover, the gas inlet pipe being upstream of the gas channel of the sealing cover.

18. The plasma etching apparatus of claim 17, wherein the pneumatic purging apparatus further comprises:
a second O-ring surrounding the circumferential wall of the sealing cover, the second O-ring being at a higher elevation than the first O-ring.

19. The plasma etching apparatus of claim 17, wherein the pneumatic purging apparatus further comprises:
two handles at opposite sides of the gas inlet pipe.

20. The plasma etching apparatus of claim 17, wherein the pneumatic purging apparatus further comprises:
a plurality of brackets extending from the bottom surface of the sealing cover.
